(19) United States
(12) Patent Application Publication
(10) Pub. No.: US 2023/0194987 A1
(43) Pub. Date: Jun. 22, 2023

(54) PHOTORESIST POLYMER AND PHOTORESIST COMPOSITION INCLUDING THE SAME

(71) Applicant: SAMSUNG ELECTRONICS CO., LTD., Suwon-si (KR)

(72) Inventors: Hyunji SONG, Suwon-si (KR); Sumin KIM, Suwon-si (KR); Hyunwoo KIM, Seongnam-si (KR); Juhyeon PARK, Hwaseong-si (KR)

(21) Appl. No.: 18/084,718

(22) Filed: Dec. 20, 2022

(30) Foreign Application Priority Data
Dec. 21, 2021 (KR) 10-2021-0184293

(51) Int. Cl. G03F 7/039

(52) U.S. Cl. CPC G03F 7/0392

(57) ABSTRACT

A photoresist polymer and a photoresist composition, the photoresist polymer including a first repeating unit represented by Chemical Formula 1:

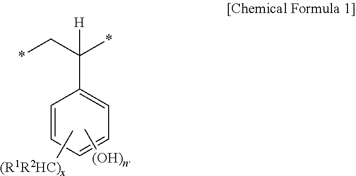

### CROSS-REFERENCE TO RELATED APPLICATION

This application is based on and claims priority under 35 U.S.C. § 119 to Korean Patent Application No. 10-2021-0184293, filed on Dec. 21, 2021, in the Korean Intellectual Property Office, the disclosure of which is incorporated by reference herein in its entirety.

### BACKGROUND

### 1. Field

Embodiments relate to a photoresist polymer and a photoresist composition including the photoresist polymer.

### 2. Description of the Related Art

According to the great advancement of electronics technology and the demand of users, semiconductors have been further reduced in size. To form semiconductor fine patterns, lithography processes using extreme ultraviolet (EUV) light have been performed.

### SUMMARY

The embodiments may be realized by providing a photoresist polymer including a first repeating unit represented by Chemical Formula 1:

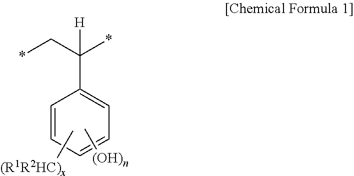

wherein, in Chemical Formula 1, R¹ and R² are each independently a hydrogen atom, an alkyl group having 1 to 10 carbon atoms, an aryl group having 6 to 20 carbon atoms, or an aralkyl group having 7 to 20 carbon atoms, provided that at least one of R¹ and R² is not a hydrogen atom, CHR¹R² is bonded at an ortho position or a para position with respect to a hydroxyl group of Chemical Formula 1, and n and x are each independently an integer of 1 to 3.

The embodiments may be realized by providing a photoresist polymer including a first repeating unit represented by Chemical Formula 7:

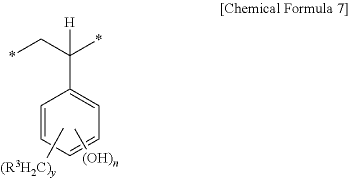

wherein, in Chemical Formula 7, R³ is an aromatic ring having 6 to 20 carbon atoms, CH₂R³ is bonded at an ortho position or a para position with respect to a hydroxyl group of Chemical Formula 7, and n and y are each independently an integer of 1 to 3.

The embodiments may be realized by providing

a photoresist composition including a photoresist polymer including a first repeating unit represented by Chemical Formula 1 or 7, and a second repeating unit represented by Chemical Formula 2; a photoacid generator; a photo-decomposable quencher; and a solvent,

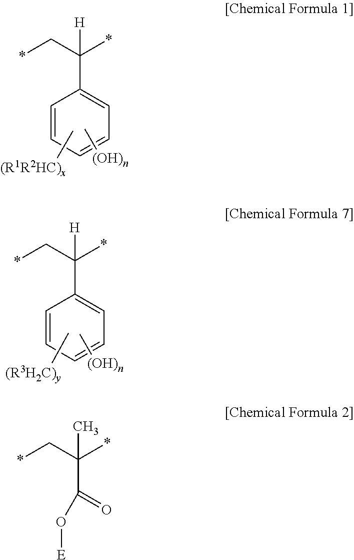

wherein, in Chemical Formula 1, R¹ and R² are each independently a hydrogen atom, an alkyl group having 1 to 10 carbon atoms, an aryl group having 6 to 20 carbon atoms, or an aralkyl group having 7 to 20 carbon atoms, provided that at least one of R¹ and R² is not a hydrogen atom, CHR¹R² is bonded at an ortho position or a para position with respect to a hydroxyl group of Chemical Formula 1, and n and x are each an integer of 1 to 3,

wherein, in Chemical Formula 7, R³ is an aromatic ring having 6 to 20 carbon atoms,

CH₂R³ is bonded at an ortho position or a para position with respect to a hydroxyl group of Chemical Formula 7, and n and y are each an integer of 1 to 3,

wherein, in Chemical Formula 2, E is a monovalent acid-labile protecting group.

### BRIEF DESCRIPTION OF THE DRAWINGS

Features will be apparent to those of skill in the art by describing in detail exemplary embodiments with reference to the attached drawings in which:

FIG. 1 is a flowchart of a method of manufacturing an integrated circuit device, according to an example embodiment;

FIGS. 2A to 2E are cross-sectional views of stages in a method of manufacturing an integrated circuit device, according to an example embodiment; and

FIGS. 3A to 3C are cross-sectional views of stages in a method of manufacturing an integrated circuit device, according to an example embodiment.

### DETAILED DESCRIPTION

An example embodiment may provide a photoresist polymer including a first repeating unit represented by Chemical Formula 1.

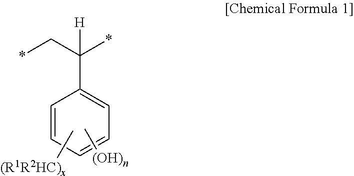

In Chemical Formula 1, R¹ and R² may each independently be or include, e.g., a hydrogen atom, an alkyl group having 1 to 10 carbon atoms, an aryl group having 6 to 20 carbon atoms, or an aralkyl group having 7 to 20 carbon atoms. In an implementation, at least one of R¹ and R² may not be a hydrogen atom. CHR′R² may be bonded at an ortho position or a para position with respect to a hydroxyl group of Chemical Formula 1. n and x may each independently be, e.g., an integer of 1 to 3. In an implementation, n and x may not both simultaneously be 3. As used herein, the term “or” is not an exclusive term, e.g., “A or B” would include A, B, or A and B. In addition, throughout the instant application, unless described otherwise, the groups of the chemical formulae, e.g., the alkyl group, the aryl group, and the like, may be unsubstituted, or may be substituted with a suitable substituent. In addition, as used herein “*” of the chemical formulae designates a bonding location.

In an implementation, R¹ and R² may each independently be, e.g., a methyl group, an ethyl group, an n-propyl group, an isopropyl group, an n-butyl group, a t-butyl group, a phenyl group, a tolyl group, a dimethylphenyl group, or a naphthyl group.

In an implementation, the photoresist polymer may further include a second repeating unit including an acid-labile protecting group. In an implementation, the photoresist polymer may be a copolymer (e.g., a random copolymer, a block copolymer, a graft copolymer, or the like).

In an implementation, the second repeating unit may include a structure represented by, e.g., Chemical Formula 2.

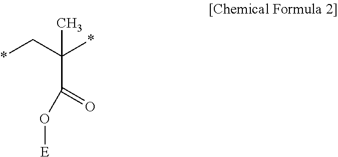

In Chemical Formula 2, E may be or may include, e.g., a monovalent acid-labile protecting group. In an implementation, E may be a substituted methyl group, a 1-substituted ethyl group, a 1-branched alkyl group, a triorganosilyl group, an alkoxycarbonyl group, an acyl group, a cyclic acid-labile protecting group, or the like.

The substituted methyl group may include, e.g., a methoxymethyl group, a methylthiomethyl group, an ethoxymethyl group, an ethylthiomethyl group, a methoxyethoxymethyl group, a benzyloxymethyl group, a benzylthiomethyl group, a phenacyl group, a bromophenacyl group, a methoxyphenacyl group, a methylthiophenacyl group, an α-methylphenacyl group, a cyclopropylmethyl group, a benzyl group, a diphenylmethyl group, a triphenylmethyl group, a bromobenzyl group, a nitrobenzyl group, a methoxybenzyl group, a methylthiobenzyl group, an ethoxybenzyl group, an ethylthiobenzyl group, a piperonyl group, a methoxycarbonylmethyl group, an ethoxycarbonylmethyl group, an n-propoxycarbonylmethyl group, an i-propoxycarbonylmethyl group, an n-butoxycarbonylmethyl group, a t-butoxycarbonylmethyl group, an adamantylmethyl group, or the like.

In an implementation, the 1-substituted ethyl group may include, e.g., a 1-methoxyethyl group, a 1-methylthioethyl group, a 1,1-dimethoxyethyl group, a 1-ethoxyethyl group, a 1-ethylthioethyl group, a 1,1-diethoxyethyl group, a 1-ethoxypropyl group, a 1-propoxyethyl group, a 1-cyclohexyloxyethyl group, a 1-phenoxyethyl group, a 1-phenylthioethyl group, a 1,1-diphenoxyethyl group, a 1-benzyloxyethyl group, a 1-benzylthioethyl group, a 1-cyclopropylethyl group, a 1-phenylethyl group, a 1,1-diphenylethyl group, a 1-methoxycarbonylethyl group, a 1-ethoxycarbonylethyl group, a 1-n-propoxycarbonylethyl group, a 1-isopropoxycarbonylethyl group, a 1-n-butoxycarbonylethyl group, a 1-t-butoxycarbonylethyl group, or the like.

In an implementation, the 1-branched alkyl group may include, e.g., an i-propyl group, a sec-butyl group, a t-butyl group, a 1,1-dimethylpropyl group, a 1-methylbutyl group, a 1,1-dimethylbutyl group, or the like.

In an implementation, the triorganosilyl group may include, e.g., a tricarbylsilyl group, such as a trimethylsilyl group, an ethyldimethylsilyl group, a methyldiethylsilyl group, a triethylsilyl group, an i-propyldimethylsilyl group, a methyldi-i-propylsilyl group, a tri-i-propylsilyl group, a t-butyldimethylsilyl group, a methyldi-t-butylsilyl group, a tri-t-butylsilyl group, a phenyldimethylsilyl group, a methyldiphenylsilyl group, or a triphenylsilyl group.

In an implementation, the alkoxycarbonyl group may include, e.g., a methoxycarbonyl group, an ethoxycarbonyl group, an i-propoxycarbonyl group, a t-butoxycarbonyl group, or the like.

In an implementation, the acyl group may include, e.g., an acetyl group, a propionyl group, a butyryl group, a heptanoyl group, a hexanoyl group, a valeryl group, a pivaloyl group, an isovaleryl group, a lauroyl group, a myristoyl group, a palmitoyl group, a stearoyl group, an oxalyl group, a malonyl group, a succinyl group, a glutaryl group, an adipoyl group, a piperoyl group, a suberoyl group, an azelaoyl group, a sebacoyl group, an acryloyl group, a propioloyl group, a methacryloyl group, a crotonoyl group, an oleoyl group, a maleoyl group, a fumaroyl group, a mesaconoyl group, a camphoroyl group, a benzoyl group, a phthaloyl group, an isophthaloyl group, a terephthaloyl group, a naphthoyl group, a toluoyl group, a hydroatropoyl group, an atropoyl group, a cinnamoyl group, a furoyl group, a thenoyl group, a nicotinoyl group, an isonicotinoyl group, a p-toluenesulfonyl group, a mesyl group, or the like.

In an implementation, the cyclic acid-labile protecting group may include, e.g., a cyclopropyl group, a cyclopentyl group, a 1-methylcyclopentyl group, a 1-ethylcyclopentyl group, a 1-isopropylcyclopentyl group, a cyclohexyl group, a 1-methylcyclohexyl group, a 1-ethylcyclohexyl group, a 1-isopropylcyclohexyl group, a 4-methoxycyclohexyl group, a cyclohexenyl group, a tetrahydropyranyl group, a tetrahydrofuranyl group, a tetrahydrothiopyranyl group, a tetrahydrothiofuranyl group, a 3-bromotetrahydropyranyl group, a 4-methoxytetrahydropyranyl group, a 4-methoxytetrahydrothiopyranyl group, a norbornyl group, a methylnorbornyl group, an ethylnorbornyl group, an isobornyl group, a tricyclodecanyl group, a dicyclopentenyl group, an adamantyl group, a 2-methyl-2-adamantyl group, a 2-ethyl-2-adamantyl group, or the like.

In an implementation, CHR¹R² in Chemical Formula 1 may be, e.g., an isopropyl group.

In an implementation, R¹ and R² in Chemical Formula 1 may be different from each other. In an implementation, R¹ in Chemical Formula 1 may be a methyl group, and R² in Chemical Formula 1 may be an ethyl group. In an implementation, R¹ and R² in Chemical Formula 1 may be identical to each other.

In an implementation, Chemical Formula 1 may be represented by, e.g., Chemical Formula 3A, Chemical Formula 3B, Chemical Formula 3C, Chemical Formula 3D, or Chemical Formula 3E.

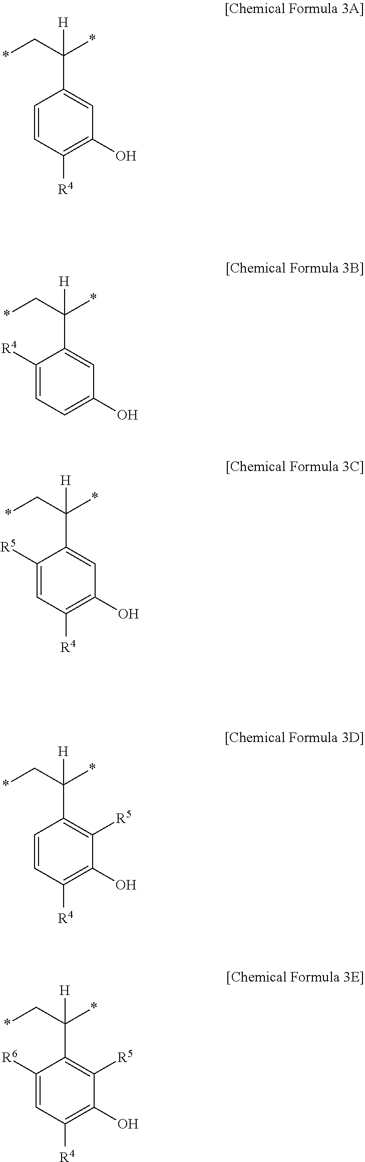

In Chemical Formulae 3A to 3E, R⁴, R⁵, and R⁶ may each independently be, e.g., CHR¹R² of Chemical Formula 1, and may be different from each other.

In an implementation, Chemical Formula 1 may be represented by, e.g., Chemical Formula 4A or Chemical Formula 4B.

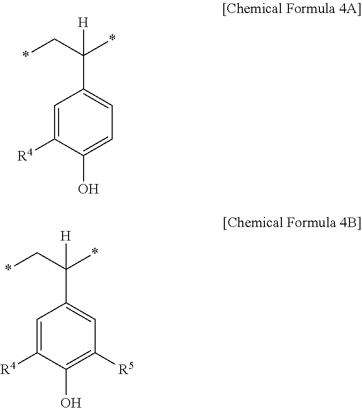

In Chemical Formulae 4A and 4B, R⁴ and R⁵ may each independently be, e.g., CHR¹R² of Chemical Formula 1, and may be different from each other.

In an implementation, Chemical Formula 1 may be represented by, e.g., Chemical Formula 5A, Chemical Formula 5B, or Chemical Formula 5C.

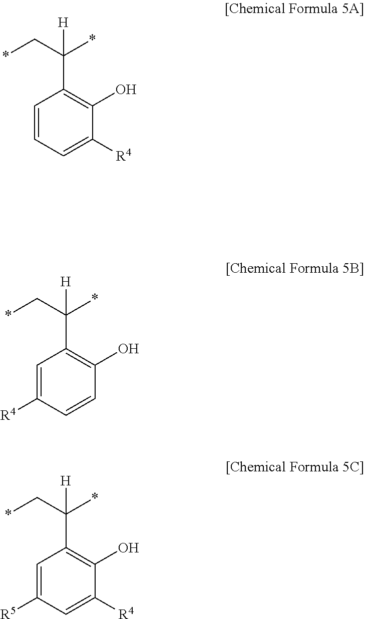

In Chemical Formulae 5A to 5C, R⁴ and R⁵ may each independently be, e.g., CHR¹R² of Chemical Formula 1, and may be different from each other.

In an implementation, the photoresist polymer including the first repeating unit represented by Chemical Formula 1 and the second repeating unit represented by Chemical Formula 2 may further include a third repeating unit represented by, e.g., Chemical Formula 6.

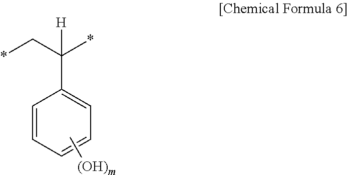

In Chemical Formula 6, m may be, e.g., an integer of 1 to 3.

In an implementation, a molar proportion of the second repeating unit of the photoresist polymer, which photoresist polymer includes the first repeating unit, the second repeating unit, and the third repeating unit, may range from, e.g., about 20 mol % to about 80 mol %, based on a total number of moles of repeating units of the photoresist polymer. In an implementation, a sum of a molar proportion of the first repeating unit and a molar proportion of the third repeating unit may range from, e.g., about 20 mol % to about 80 mol %. In an implementation, the molar proportion of the second repeating unit may be 60 mol %, the molar proportion of the first repeating unit may be 30 mol %, and the molar proportion of the third repeating unit may be 10 mol %. In an implementation, the molar proportion of the second repeating unit of the photoresist polymer, which includes the first repeating unit, the second repeating unit, and the third repeating unit, may range from about 30 mol % to about 70 mol %, and the sum of the molar proportion of the first repeating unit and the molar proportion of the third repeating unit may range from about 30 mol % to about 70 mol %. In an implementation, the molar proportion of the second repeating unit of the photoresist polymer, which includes the first repeating unit, the second repeating unit, and the third repeating unit, may range from about 40 mol % to about 60 mol %, and the sum of the molar proportion of the first repeating unit and the molar proportion of the third repeating unit may range from about 40 mol % to about 60 mol %.

The photoresist polymer according to an embodiment may include the first repeating unit having a structure represented by Chemical Formula 1. The first repeating unit may be hydroxystyrene having CHR¹R² at an ortho position or para position with respect to a hydroxyl group. The first repeating unit may have a lower reduction potential than that of other hydroxystyrene repeating units, and the first repeating unit may generate more secondary electrons and protons when the same exposure energy (dose) is applied thereto. In an implementation, the productivity of a manufacturing process of an integrated circuit device may be improved, and the dispersion of patterns may be improved.

An embodiment may provide a photoresist polymer including a first repeating unit represented by Chemical Formula 7.

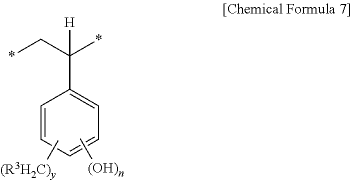

In Chemical Formula 7, R³ may be or may include, e.g., an aromatic ring having 6 to 20 carbon atoms. CH₂R³ may be bonded at an ortho position or a para position with respect to a hydroxyl group of Chemical Formula 7. n and y may each independently be, e.g., an integer of 1 to 3. In an implementation, n and y may not both simultaneously be 3.

In an implementation, Chemical Formula 7 may be represented by, e.g., Chemical Formula 8A, Chemical Formula 8B, Chemical Formula 8C, Chemical Formula 8D, or Chemical Formula 8E.

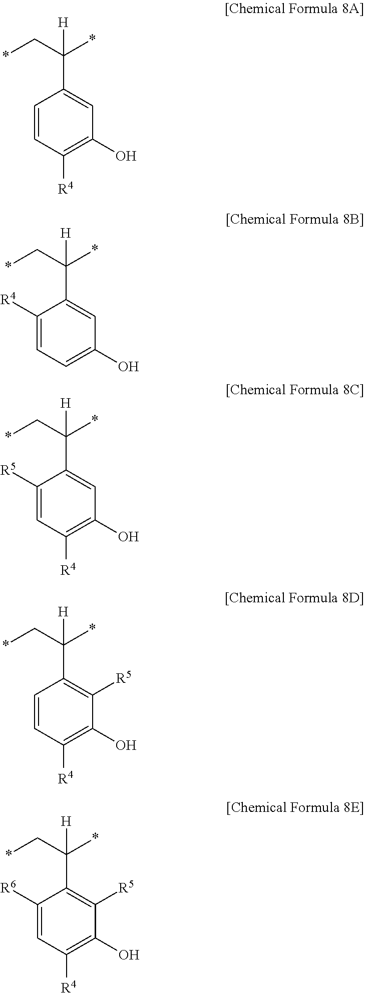

In Chemical Formulae 8A to 8E, R⁴, R⁵, and R⁶ may each independently be, e.g., CH₂R³ of Chemical Formula 7 and may be different from each other.

In an implementation, Chemical Formula 7 may be represented by, e.g., Chemical Formula 9A or Chemical Formula 9B.

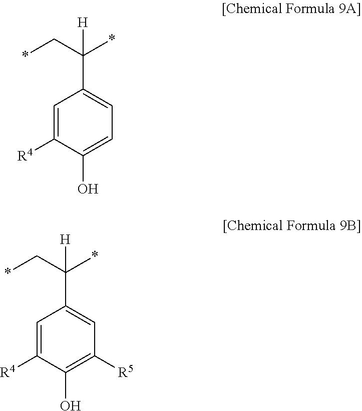

In Chemical Formulae 9A and 9B, R⁴ and R⁵ may each independently be, e.g., CH₂R³ of Chemical Formula 7 and may be different from each other.

In an implementation, Chemical Formula 7 may be represented by, e.g., Chemical Formula 10A, Chemical Formula 10B, or Chemical Formula 10C.

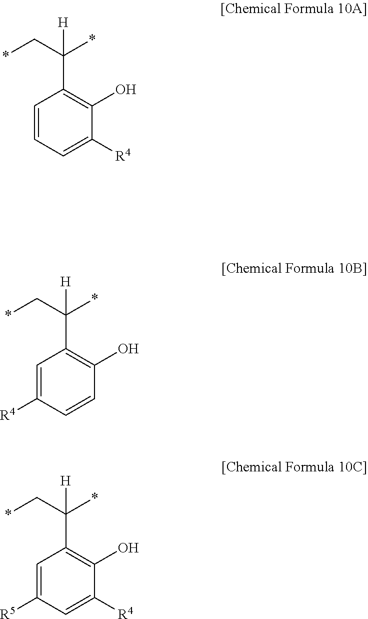

In Chemical Formulae 10A to 10C, R⁴ and R⁵ may each independently be, e.g., CH₂R³ of Chemical Formula 7 and may be different from each other.

In an implementation, the photoresist polymer including the first repeating unit represented by Chemical Formula 7 may further include, e.g., a second repeating unit represented by Chemical Formula 2.

In an implementation, the photoresist polymer including the first repeating unit represented by Chemical Formula 7 and the second repeating unit represented by Chemical Formula 2 may further include, e.g., a third repeating unit represented by Chemical Formula 6.

In an implementation, a molar proportion of the second repeating unit of the photoresist polymer, which photoresist polymer includes the first repeating unit represented by Chemical Formula 7, the second repeating unit, and the third repeating unit, may range from, e.g., about 20 mol % to about 80 mol %, and a sum of a molar proportion of the first repeating unit and a molar proportion of the third repeating unit may range from, e.g., about 20 mol % to about 80 mol %. In an implementation, the molar proportion of the second repeating unit may be 60 mol %, the molar proportion of the first repeating unit may be 30 mol %, and the molar proportion of the third repeating unit may be 10 mol %. In an implementation, the molar proportion of the second repeating unit of the photoresist polymer, which includes the first repeating unit, the second repeating unit, and the third repeating unit, may range from about 30 mol % to about 70 mol %, and the sum of the molar proportion of the first repeating unit and the molar proportion of the third repeating unit may range from about 30 mol % to about 70 mol %. In an implementation, the molar proportion of the second repeating unit of the photoresist polymer, which includes the first repeating unit, the second repeating unit, and the third repeating unit, may range from about 40 mol % to about 60 mol %, and the sum of the molar proportion of the first repeating unit and the molar proportion of the third repeating unit may range from about 40 mol % to about 60 mol %.

The photoresist polymer according to an embodiment may include the first repeating unit having a structure represented by Chemical Formula 7. The first repeating unit includes hydroxystyrene moiety having CH₂R³ at an ortho position or para position with respect to a hydroxyl group. The first repeating unit may have a lower reduction potential than that of other hydroxystyrene repeating units, the first repeating unit may generate more secondary electrons and protons at the same exposure energy (dose). In an implementation, the productivity of a manufacturing process of an integrated circuit device may be improved, and the dispersion of patterns may be improved. Hereinafter, an oxidation process of the first repeating unit represented by Chemical Formula 1 will be described through Reaction Formula 1.

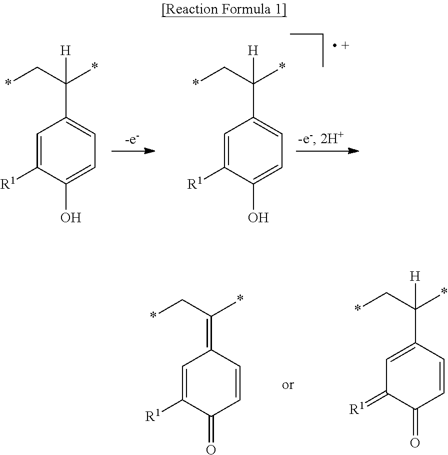

Reaction Formula 1 illustrates an oxidation process of the first repeating unit represented by Chemical Formula 1 when Chemical Formula 1 is represented by Chemical Formula 4A. Referring to Reaction Formula 1, the first repeating unit may be oxidized as in Reaction Formula 1 by losing an electron. In an implementation, the first repeating unit may have a substituent at an ortho position with respect to a hydroxyl group, and an oxidized structure of the first repeating unit may be further stabilized than a structure not having a substituent at a specific position. Secondary electrons and protons may be more easily generated when the oxidized structure of the first repeating unit is stabilized, the productivity of a manufacturing process of an integrated circuit device using the photoresist polymer including the first repeating unit may be improved, and the dispersion of patterns may be improved.

The photoresist polymer may include a positive photoresist. The positive photoresist may include, e.g., a photoresist for KrF excimer lasers (248 nm), a photoresist for ArF excimer lasers (193 nm), a photoresist for F₂ excimer lasers (157 nm), or a photoresist for extreme ultraviolet (EUV) (13.5 nm).

In an implementation, the photoresist polymer may have a weight average molecular weight of, e.g., about 1,000 to about 500,000.

An embodiment may provide a photoresist composition including, e.g., a photoresist polymer including a first repeating unit represented by Chemical Formula 1 or 7 and a second repeating unit represented by Chemical Formula 2; a photoacid generator; and a solvent.

Regarding the photoresist polymer, a reference may be made to the descriptions given above.

In an implementation, the photoresist polymer included in the photoresist composition may further include, e.g., a third repeating unit represented by Chemical Formula 6.

In an implementation, a molar proportion of the second repeating unit of the photoresist polymer, which photoresist polymer includes the first repeating unit, the second repeating unit, and the third repeating unit, may range from, e.g., about 20 mol % to about 80 mol %, and a sum of a molar proportion of the first repeating unit and a molar proportion of the third repeating unit may range from, e.g., about 20 mol % to about 80 mol %. In an implementation, the molar proportion of the second repeating unit may be 60 mol %, the molar proportion of the first repeating unit may be 30 mol %, and the molar proportion of the third repeating unit may be 10 mol %. In an implementation, the molar proportion of the second repeating unit of the photoresist polymer, which includes the first repeating unit, the second repeating unit, and the third repeating unit, may range from about 30 mol % to about 70 mol %, and the sum of the molar proportion of the first repeating unit and the molar proportion of the third repeating unit may range from about 30 mol % to about 70 mol %. In an implementation, the molar proportion of the second repeating unit of the photoresist polymer, which includes the first repeating unit, the second repeating unit, and the third repeating unit, may range from about 40 mol % to about 60 mol %, and the sum of the molar proportion of the first repeating unit and the molar proportion of the third repeating unit may range from about 40 mol % to about 60 mol %.

The photoacid generator may generate an acid when exposed to light of, e.g., a KrF excimer laser (248 nm), an ArF excimer laser (193 nm), an F₂ excimer laser (157 nm), or an EUV laser (13.5 nm). The photoacid generator may include a material generating a relatively strong acid, which has an acid dissociation constant (pKa) equal to or greater than about −20 and less than about 1, by exposure. The photoacid generator may include, e.g., triarylsulfonium salts, diaryliodonium salts, sulfonates, or mixtures thereof. In an implementation, the photoacid generator may include, e.g., triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonate, pyrogallol tris(alkylsulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS, or a mixture thereof.

The solvent may include an organic solvent. In an implementation, the solvent may include, e.g., ethers, alcohols, glycol ethers, aromatic hydrocarbon compounds, ketones, or esters. In an implementation, the solvent may include, e.g., ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol monoethyl ether, propylene glycol monoethyl ether acetate, propylene glycol propyl ether acetate, propylene glycol monobutyl ether, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, or the like. These solvents may be used alone or in a combination of at least two thereof.

In an implementation, the photoresist composition may further include, e.g., a basic proton quencher or a photo-decomposable quencher (PDQ).

The basic proton quencher and the PDQ may each include a compound capable of neutralizing an acid in a non-exposed region of a photoresist film, when the acid generated from the photoacid generator diffuses into the non-exposed region. The photoresist composition may include the basic proton quencher, whereby an acid may be suppressed from diffusing into an unintended region.

In an implementation, the basic proton quencher may include, e.g., primary aliphatic amines, secondary aliphatic amines, tertiary aliphatic amines, aromatic amines, heterocyclic ring-containing amines, nitrogen-containing compounds having carboxyl groups, nitrogen-containing compounds having sulfonyl groups, nitrogen-containing compounds having hydroxyl groups, nitrogen-containing compounds having hydroxyphenyl groups, alcoholic nitrogen-containing compounds, amides, imides, carbamates, or ammonium salts. In an implementation, the basic proton quencher may include, e.g., triethanolamine, triethylamine, tributylamine, tripropylamine, hexamethyldisilazan, aniline, N-methylaniline, N-ethylaniline, N-propylaniline, N,N-dimethylaniline, N,N-bis(hydroxyethyl)aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or a combination thereof.

In an implementation, the PDQ may include triarylsulfonium salts, diaryliodonium salts, or mixtures thereof. In an implementation, the PDQ may include, e.g., triphenylsulfonium salicylate, triphenylsulfonium benzoate, triphenylsulfonium cyclohexylcarboxylate, diphenyliodonium salicylate, diphenyliodonium benzoate, methoxydiphenyliodonium salicylate, di-t-butyldiphenyliodonium salicylate, or a combination thereof.

In an implementation, the photoresist composition may further include a surfactant.

The surfactant may include, e.g., fluoroalkylbenzene sulfonates, fluoroalkyl carboxylates, fluoroalkyl polyoxyethylene ethers, fluoroalkyl ammonium iodides, fluoroalkyl betaines, fluoroalkyl sulfonates, diglycerin tetrakis (fluoroalkyl polyoxyethylene ethers), fluoroalkyl trimethylammonium salts, fluoroalkyl aminosulfonates, polyoxyethylene nonylphenyl ether, polyoxyethylene octylphenyl ether, polyoxyethylene alkyl ethers, polyoxyethylene lauryl ether, polyoxyethylene oleyl ether, polyoxyethylene tridecyl ether, polyoxyethylene cetyl ether, polyoxyethylene stearyl ether, polyoxyethylene laurate, polyoxyethylene oleate, polyoxyethylene stearate, polyoxyethylene lauryl amine, sorbitan laurate, sorbitan palmitate, sorbitan stearate, sorbitan oleate, sorbitan fatty acid esters, polyoxyethylene sorbitan laurate, polyoxyethylene sorbitan palmitate, polyoxyethylene sorbitan stearate, polyoxyethylene sorbitan oleate, polyoxyethylene naphthyl ether, alkylbenzene sulfonates, or alkyl diphenyl ether disulfonates.

In an implementation, the photoresist composition may further include, e.g., a pigment, a preservative, an adhesion promoter, a coating aid, a plasticizer, a surface modifying agent, or a dissolution inhibitor.

The photoresist composition according to an embodiment may include, e.g., the photoresist polymer including the first repeating unit having a structure represented by Chemical Formula 1. The first repeating unit may include a hydroxystyrene moiety having a substituent at an ortho or para position. The first repeating unit may have a lower reduction potential than that of existing hydroxystyrene, and the first repeating unit may generate more secondary electrons at the same exposure energy (dose). In an implementation, the productivity of a manufacturing process of an integrated circuit device may be improved, and the dispersion of patterns may be improved.

Next, a method of manufacturing an integrated circuit device by using a photoresist composition, according to an embodiment, is described.

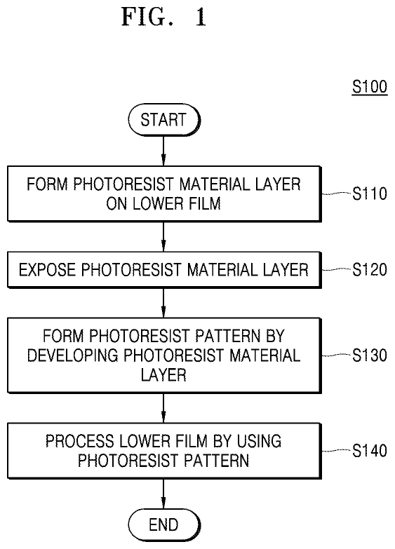

FIG. 1 is a flowchart of a method of manufacturing an integrated circuit device, according to an example embodiment.

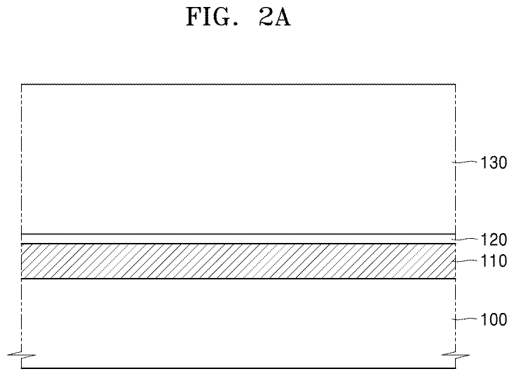

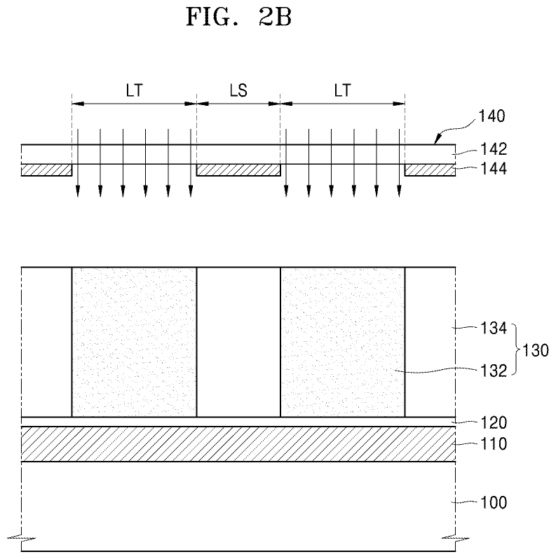

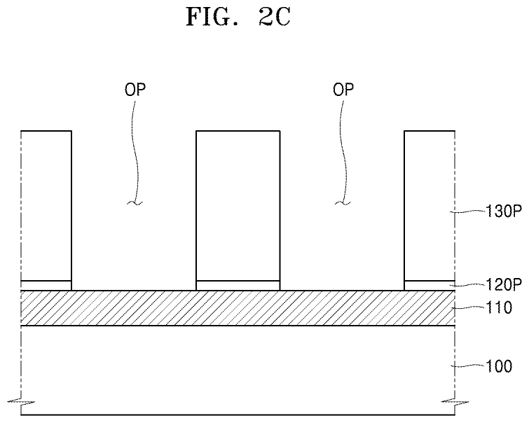

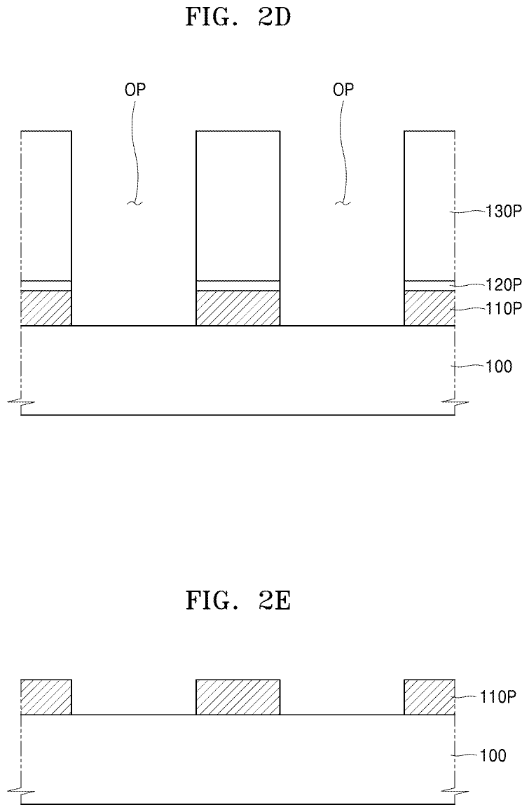

FIGS. 2A to 2E are cross-sectional views of stages in a method of manufacturing an integrated circuit device, according to an example embodiment. Specifically, FIGS. 2A to 2E are cross-sectional views of stages in a method of manufacturing an integrated circuit device by using a positive-tone developer.

Referring to FIGS. 1 and 2A, in operation S110, a photoresist film 130 may be formed on a lower film 120 on a substrate 100.

The photoresist film 130 may include a photoresist composition according to an embodiment. More detailed descriptions of the photoresist composition are the same as given above.

The substrate 100 may include a semiconductor substrate. In an implementation, the substrate 100 may include, e.g., a semiconductor material, such as Si or Ge, or a compound semiconductor material, such as SiGe, SiC, GaAs, InAs, or InP.

A feature layer 110 may be on the substrate 100 and may include an insulating film, a conductive film, or a semiconductor film. In an implementation, the feature layer 110 may include, e.g., a metal, an alloy, a metal carbide, a metal nitride, a metal oxynitride, a metal oxycarbide, a semiconductor, polysilicon, an oxide, a nitride, an oxynitride, or a combination thereof.

In an implementation, as shown in FIG. 2A, the lower film 120 may be formed on the feature layer 110. The lower film 120 may help prevent the photoresist film 130 from being adversely affected by the feature layer 110 under the photoresist film 130. In an implementation, the lower film 120 may include an organic or inorganic anti-reflective coating (ARC) material for KrF excimer lasers, ArF excimer lasers, EUV lasers, or other light sources. In an implementation, the lower film 120 may include a bottom anti-reflective coating (BARC) film or a developable bottom anti-reflective coating (DBARC) film. In an implementation, the lower film 120 may include an organic component having a light absorption structure. The light absorption structure may include, e.g., a hydrocarbon compound having a structure in which one or more benzene rings are fused. The lower film 120 may a thickness of, e.g., about 1 nm to about 100 nm. In an implementation, the lower film 120 may be omitted.

To form the photoresist film 130, the photoresist composition according to an embodiment may be coated on the lower film 120. The coating may be performed by, e.g., spin coating, spray coating, dip coating, or the like. The thickness of the photoresist film 130 may be tens to hundreds of times the thickness of the lower film 120. The photoresist film 130 may have a thickness of, e.g., about 10 nm to about 1 μm.

In an implementation, before operation S120 is performed, a first bake may be performed on the photoresist film 130. The first bake may be referred to as post-apply bake (PAB).

The first bake may be performed at a temperature of about 80° C. to about 140° C. or about 90° C. to about 120° C. for about 10 seconds to about 100 seconds. If the temperature of the first bake were to be too low, the solvent could be insufficiently removed. If the temperature of the first bake were to be too high, a resolution of a photoresist pattern could deteriorate.

Referring to FIGS. 1 and 2B, in operation S120, by exposing a first region 132, e.g., a portion of the photoresist film 130, an acid may be generated from a photoacid generator in the photoresist composition in the first region 132.

In an implementation, to expose the first region 132 of the photoresist film 130, a photomask 140, which has a plurality of light shielding areas LS and a plurality of light transmitting areas LT, may be aligned at a certain position over the photoresist film 130, and the first region 132 of the photoresist film 130 may be exposed through the plurality of light transmitting areas LT of the photomask 140. To expose the first region 132 of the photoresist film 130, a KrF excimer laser (248 nm), an ArF excimer laser (193 nm), an F₂ excimer laser (157 nm), or an EUV laser (13.5 nm) may be used. In an implementation, a reflective photomask may be used instead of a transmissive photomask, according to the type of light source. Although the following descriptions are made by mainly taking a transmissive photomask as an example, the exposure may also be performed by an equivalent configuration by using a reflective photomask.

The photomask 140 may include a transparent substrate 142, and a plurality of light shielding patterns 144 in the plurality of light shielding areas LS on the transparent substrate 142. The transparent substrate 142 may include quartz. The plurality of light shielding patterns 144 may include chromium (Cr). The plurality of light transmitting areas LT may be defined by the plurality of light shielding patterns 144.

After the first region 132 of the photoresist film 130 is exposed according to operation S120, the photoresist film 130 may undergo a second bake. The second bake may be referred to as post-exposure bake (PEB). In an implementation, the second bake may be performed at a temperature of about 50° C. to about 400° C. for about 10 seconds to about 100 seconds. In an implementation, as the second bake may be performed on the photoresist film 130, an acid-labile protecting group included in a second repeating unit of a photoresist polymer in the first region 132 may be changed into a carboxylic acid functional group exhibiting acidity, the second repeating unit being represented by Chemical Formula 2. Accordingly, a difference in solubility in a developer between the exposed first region 132 and a non-exposed second region 134 of the photoresist film 130 may be further increased, and the exposed first region 132 or the non-exposed second region 134 may be selectively removed according to the type of developer, thereby forming a pattern.

Referring to FIGS. 1 and 2C, in operation S130, the exposed first region 132 of the photoresist film 130 may be removed by developing the photoresist film 130 by using, e.g., a basic water-based developer. As a result, a photoresist pattern 130P including the non-exposed second region 134 of the photoresist film 130 may be formed. The basic water-based developer may include, e.g., tetramethylammonium hydroxide (TMAH). In an implementation, to develop the photoresist film 130, an alkaline developer may be used. The alkaline developer may include a 2.38 wt % TMAH aqueous solution.

The photoresist pattern 130P may include a plurality of openings OP. After the photoresist pattern 130P is formed, a lower pattern 120P may be formed by removing portions of the lower film 120, which are exposed by the plurality of openings OP.

Referring to FIGS. 1 and 2D, in operation S140, in a resulting product of FIG. 2C, the feature layer 110 may be processed by using the photoresist pattern 130P.

To process the feature layer 110, various processes, such as a process of etching the feature layer 110 exposed by an opening OP of the photoresist pattern 130P, a process of implanting impurity ions into the feature layer 110, a process of forming an additional film on the feature layer 110 through the opening OP, and a process of modifying a portion of the feature layer 110 through the opening OP, may be performed. FIG. 2D illustrates, as an example process of processing the feature layer 110, an example of forming a feature pattern 110P by etching the feature layer 110 exposed by the opening OP.

In an implementation, the process of forming the feature layer 110 may be omitted from the process described with reference to FIG. 2A, and in this case, instead of operation S140 of FIG. 1 and the operation described with reference to FIG. 2D, the substrate 100 may be processed by using the photoresist pattern 130P. In an implementation, various processes, such as a process of etching a portion of the substrate 100 by using the photoresist pattern 130P, a process of implanting impurity ions into a certain region of the substrate 100, a process of forming an additional film on the substrate 100 through the opening OP, and a process of modifying a portion of the substrate 100 through the opening OP, may be performed.

Referring to FIG. 2E, in a resulting product of FIG. 2D, the photoresist pattern 130P and the lower pattern 120P, which remain on the feature pattern 110P, may be removed. To remove the photoresist pattern 130P and the lower pattern 120P, ashing and strip processes may be used. In accordance with the method, described with reference to FIGS. 1 and 2A to 2E, of manufacturing an integrated circuit device according to an embodiment, the photoresist polymer includes a first repeating unit having a lower reduction potential than that of other hydroxystyrene repeating units, and thus, the secondary electron generation efficiency of the photoresist polymer during exposure may be improved. Therefore, in the photoresist pattern 130P obtained by using the photoresist composition including the photoresist polymer, line edge roughness (LER) and line width roughness (LWR), which represent patterning dispersion, may be reduced, thereby providing high pattern fidelity. In addition, critical dimension (CD) dispersion of patterns intended to be implemented on the substrate 100 may be uniformly controlled, and the productivity of a manufacturing process of an integrated circuit device may be improved.

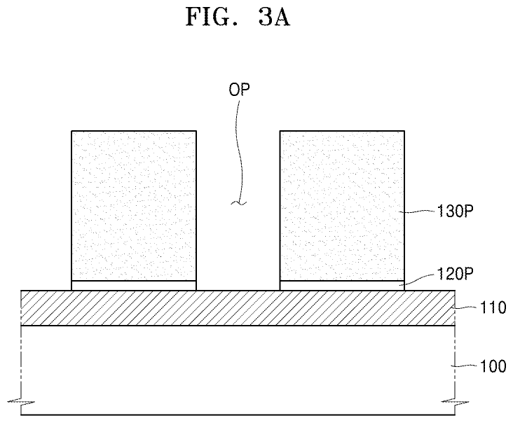

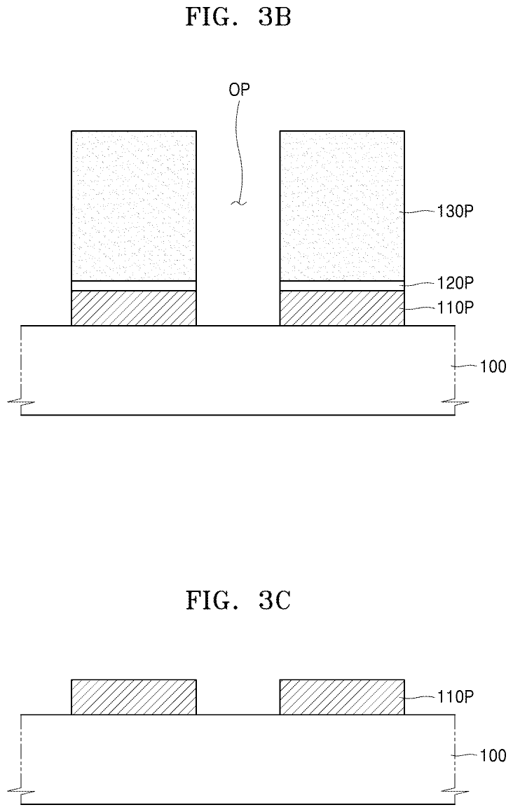

FIGS. 3A to 3C are cross-sectional views of stages in a method of manufacturing an integrated circuit device, according to an example embodiment. Specifically, FIGS. 3A to 3E are cross-sectional views of stages in a method of manufacturing an integrated circuit device by using a negative-tone developer. Hereinafter, respective operations of a method of manufacturing an integrated circuit device by using a negative-tone developer will be described by referring together to FIG. 1.

Before the respective operations of the method of manufacturing an integrated circuit device according to FIGS. 3A to 3C are performed, operations S110 and S120 described with reference to FIGS. 1 to 2B may be performed.

Referring to FIGS. 1 and 3A, in operation S130, the non-exposed second region 134 (see FIG. 2B) of the photoresist film 130 may be removed by developing the photoresist film 130 by using an organic solvent as a developer. As a result, the photoresist pattern 130P including the exposed first region 132 (see FIG. 2B) of the photoresist film 130 may be formed. In an implementation, the organic solvent may include, e.g., n-butyl acetate.

The photoresist pattern 130P may include the plurality of openings OP. After the photoresist pattern 130P is formed, the lower pattern 120P may be formed by removing portions of the lower film 120, which are exposed by the plurality of openings OP.

Referring to FIGS. 1 and 3B, in operation S140, in a resulting product of FIG. 3A, the feature layer 110 may be processed by using the photoresist pattern 130P.

Processing of the feature layer 110 may be performed by the same process as the process described with reference to FIGS. 1 and 2D. FIG. 3B illustrates, as an example process of processing the feature layer 110, an example of forming the feature pattern 110P by etching the feature layer 110 exposed by the opening OP.

Referring to FIG. 3C, in a resulting product of FIG. 3B, the photoresist pattern 130P and the lower pattern 120P, which remain on the feature pattern 110P, may be removed. To remove the photoresist pattern 130P and the lower pattern 120P, ashing and strip processes may be used. In accordance with the method, described with reference to FIGS. 1 and 3A to 3C, of manufacturing an integrated circuit device, according to an embodiment, the photoresist polymer may include a first repeating unit having a lower reduction potential than that of other hydroxystyrene repeating units, and thus, the secondary electron generation efficiency of the photoresist polymer during exposure may be improved. Therefore, in the photoresist pattern 130P obtained by using the photoresist composition including the photoresist polymer, LER and LWR may be reduced, thereby providing high pattern fidelity. In addition, the CD dispersion of patterns intended to be implemented on the substrate 100 may be uniformly controlled, and the productivity of a manufacturing process of an integrated circuit device may be improved.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

Each photoresist polymer was prepared such that respective molar proportions (mol %) of first to third repeating units were as listed in Table 1.

In addition, a photoresist composition, which included 1 wt % of each photoresist polymer, 0.3 wt % of a triphenylsulfonium difluoroalkylsulfonate as a photoacid generator, 98.5 wt % of propylene glycol methyl ether (PGME) as a solvent, and 0.2 wt % of triphenylsulfonium salicylate as a PDQ, was prepared, and a lithography process was performed by using a mask including 1:1 line-and-space patterns having a 40 nm pitch. The photoresist composition that underwent the lithography process was developed with a 2.38 wt % TMAH aqueous solution, and then, the resolution of a photoresist pattern, the dose-to-size representing exposure energy required to form a 20 nm space, and the dispersion (LER) of 1:1 40 nm-pitch line-and-space patterns formed according to the process set forth above were measured, and results thereof are shown in Table 1.

TABLE 1

| | First repeating | | Second | Third | | | |
|---|---|---|---|---|---|---|---|
| | unit | | repeating | repeating | Minimum | | |
| | | Amount | unit (B) | unit (C) | Resolution | Dose to size | LER |
| | Type | (mol %) | (mol %) | (mol %) | (nm) | (mJ/cm²) | (nm) |
| Comparative | — | — | 51 | 49 | 40 | 75 | 2.8 |
| Example 1 | | | | | | | |
| Comparative | — | — | 55 | 45 | 39 | 77 | 2.9 |
| Example 2 | | | | | | | |
| Comparative | — | — | 61 | 39 | 39 | 81 | 3.1 |
| Example 3 | | | | | | | |
| Comparative | A-3 | 12 | 52 | 36 | 39 | 72 | 2.5 |
| Example 4 | | | | | | | |
| Comparative | A-3 | 25 | 52 | 27 | 38 | 70 | 2.4 |
| Example 5 | | | | | | | |
| Example 1 | A-1 | 12 | 50 | 38 | 38 | 68 | 2.4 |
| Example 2 | A-1 | 24 | 53 | 23 | 36 | 63 | 2.2 |
| Example 3 | A-1 | 40 | 50 | 10 | 36 | 65 | 2.3 |
| Example 4 | A-2 | 10 | 60 | 30 | 37 | 69 | 2.5 |
| Example 5 | A-2 | 18 | 60 | 22 | 36 | 67 | 2.4 |
| Example 6 | A-2 | 30 | 58 | 12 | 36 | 65 | 2.3 |
| Example 7 | A-1 | 40 | 60 | — | 38 | 71 | 2.5 |
| Example 8 | A-1 | 50 | 50 | — | 37 | 70 | 2.4 |
| Example 9 | A-2 | 42 | 58 | — | 38 | 70 | 2.5 |
| Example 10 | A-2 | 49 | 51 | — | 37 | 68 | 2.4 |
| Example 11 | A-4 | 13 | 51 | 36 | 37 | 69 | 2.4 |
| Example 12 | A-4 | 25 | 51 | 24 | 36 | 66 | 2.2 |
| Example 13 | A-5 | 12 | 53 | 35 | 38 | 68 | 2.4 |
| Example 14 | A-5 | 26 | 52 | 22 | 36 | 65 | 2.3 |

In Table 1, the first to third repeating units are as follows.

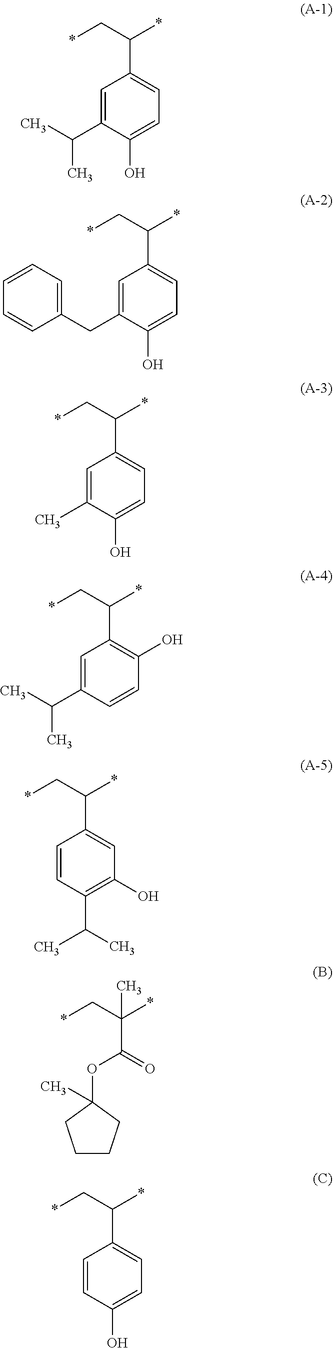

As shown in Table 1, when the photoresist polymers of Examples 1 to 14 were used, it may be that the resolution was improved because lower Minimum Resolution was implemented as compared with Comparative Examples, that the productivity was improved because lower exposure energy was required, and that the dispersion of patterns was improved because the pattern dispersion (LER) was reduced.

By way of summation and review, EUV light has a lower number of photons at the same exposure energy than existing ArF light and KrF light, a high exposure energy (dose) may be required to transfer a sufficient number of photons needed for patterning, and thus, deterioration in the productivity of lithography processes could occur. In a photoresist composition the dispersion of patterns may be improved, even while improving the productivity of a lithography process.

One or more embodiments may provide a photoresist polymer including a hydroxystyrene moiety having a substituent at a specific position.

One or more embodiments may provide a photoresist polymer capable of improving the generation efficiency of secondary electrons and acids during extreme ultraviolet (EUV) exposure.

One or more embodiments may provide a photoresist composition including a photoresist polymer capable of improving the generation efficiency of secondary electrons and acids during EUV exposure.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photoresist polymer comprising a first repeating unit represented by Chemical Formula 1: 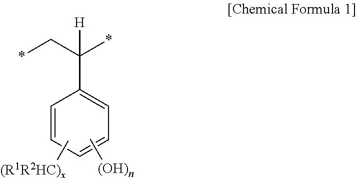
wherein, in Chemical Formula 1,
R¹ and R² are each independently a hydrogen atom, an alkyl group having 1 to 10 carbon atoms, an aryl group having 6 to 20 carbon atoms, or an aralkyl group having 7 to 20 carbon atoms, provided that at least one of R¹ and R² is not a hydrogen atom,
CHR¹R² is bonded at an ortho position or a para position with respect to a hydroxyl group of Chemical Formula 1, and
n and x are each independently an integer of 1 to 3.

2. The photoresist polymer as claimed in claim 1, further comprising a second repeating unit including an acid-labile protecting group.

3. The photoresist polymer as claimed in claim 2, wherein:
the second repeating unit includes a structure represented by Chemical Formula 2: 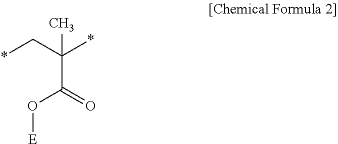
in Chemical Formula 2, E is a monovalent acid-labile protecting group.

4. The photoresist polymer as claimed in claim 1, wherein CHR¹R² in Chemical Formula 1 is an isopropyl group.

5. The photoresist polymer as claimed in claim 1, wherein R¹ and R² in Chemical Formula 1 are different from each other.

6. The photoresist polymer as claimed in claim 1, wherein:
Chemical Formula 1 is represented by Chemical Formula 3A, Chemical Formula 3B, Chemical Formula 3C, Chemical Formula 3D, or Chemical Formula 3E: 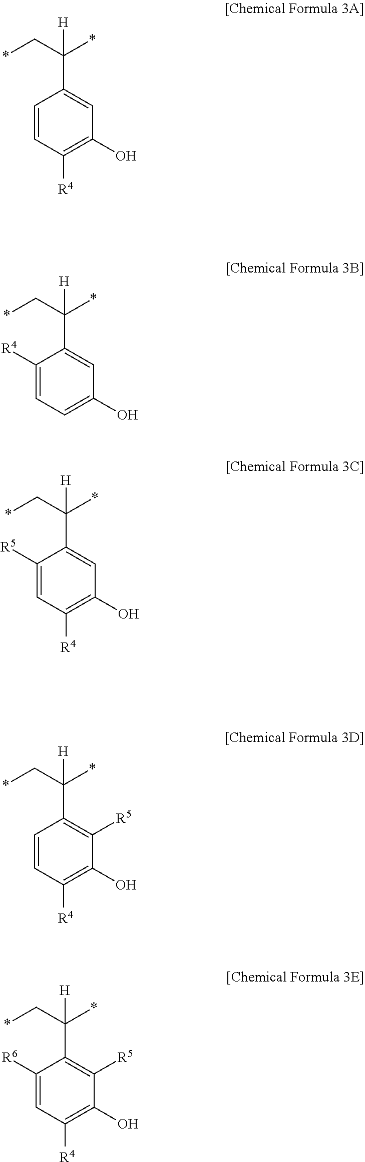
in Chemical Formulae 3A to 3E, R⁴, R⁵, and R⁶ are each independently CHR¹R² of Chemical Formula 1 and are different from each other.

7. The photoresist polymer as claimed in claim 1, wherein:
Chemical Formula 1 is represented by Chemical Formula 4A or Chemical Formula 4B: 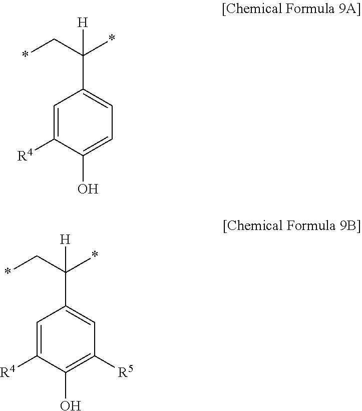
in Chemical Formulae 4A and 4B, R⁴ and R⁵ are each independently CHR¹R² of Chemical Formula 1 and are different from each other.

8. The photoresist polymer as claimed in claim 1, wherein:
Chemical Formula 1 is represented by Chemical Formula 5A, Chemical Formula 5B, or Chemical Formula 5C: 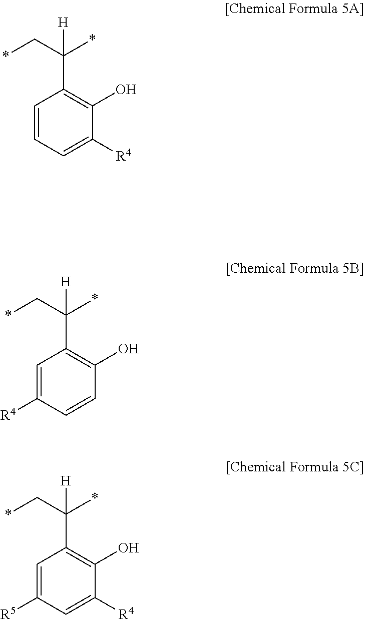
in Chemical Formulae 5A to 5C, R⁴ and R⁵ are each independently CHR¹R² of Chemical Formula 1 and are different from each other.

9. The photoresist polymer as claimed in claim 2, further comprising a third repeating unit represented by Chemical Formula 6: 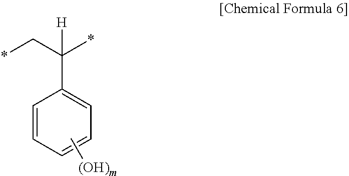
wherein, in Chemical Formula 6, m is an integer of 1 to 3.

10. The photoresist polymer as claimed in claim 9, wherein a molar proportion of the second repeating unit ranges from about 20 mol % to about 80 mol %, and a sum of a molar proportion of the first repeating unit and a molar proportion of the third repeating unit ranges from about 20 mol % to about 80 mol %, based on a total number of moles of repeating units of the photoresist polymer.

11. A photoresist polymer comprising a first repeating unit represented by Chemical Formula 7: 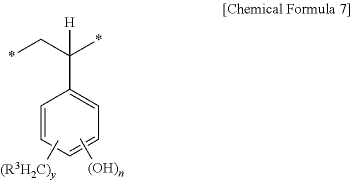
wherein, in Chemical Formula 7,
R³ is an aromatic ring having 6 to 20 carbon atoms,
CH₂R³ is bonded at an ortho position or a para position with respect to a hydroxyl group of Chemical Formula 7, and
n and y are each independently an integer of 1 to 3.

12. The photoresist polymer as claimed in claim 11, wherein:
Chemical Formula 7 is represented by Chemical Formula 8A, Chemical Formula 8B, Chemical Formula 8C, Chemical Formula 8D, or Chemical Formula 8E: 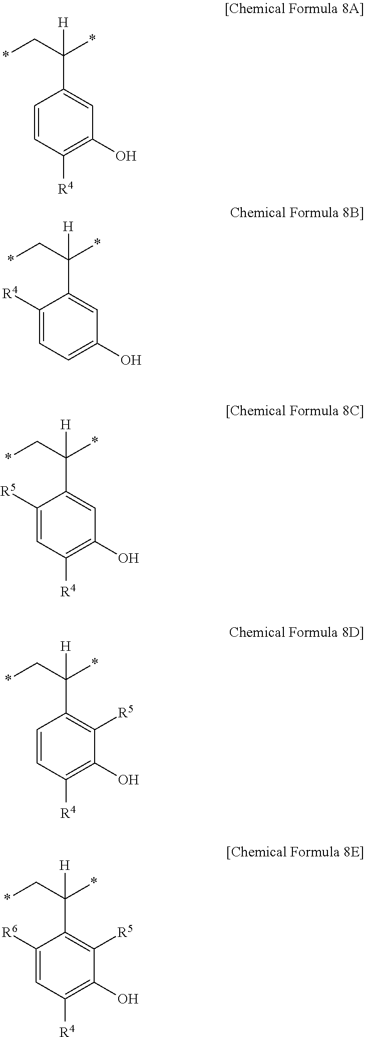
in Chemical Formulae 8A to 8E, R⁴, R⁵, and R⁶ are each independently CH₂R³ of Chemical Formula 7 and are different from each other.

13. The photoresist polymer as claimed in claim 11, wherein:
Chemical Formula 7 is represented by Chemical Formula 9A or Chemical Formula 9B: 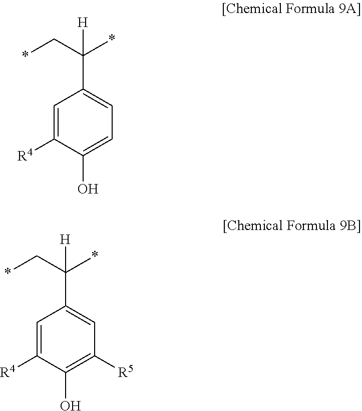
in Chemical Formulae 9A and 9B, R⁴ and R⁵ are each independently CH₂R³ of Chemical Formula 7 and are different from each other.

14. The photoresist polymer as claimed in claim 11, wherein:
Chemical Formula 7 is represented by Chemical Formula 10A, Chemical Formula 10B, or Chemical Formula 10C: 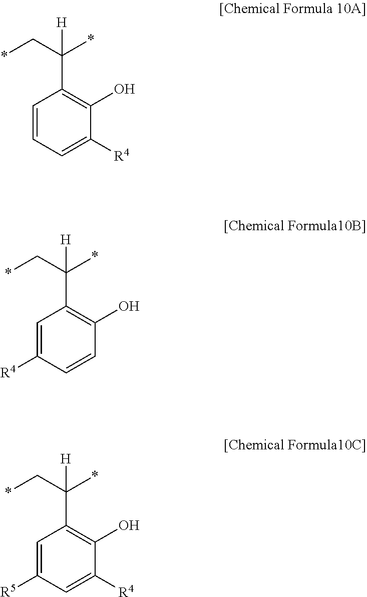
in Chemical Formulae 10A to 10C, R⁴ and R⁵ are each independently CH₂R³ of Chemical Formula 7 and are different from each other.

15. The photoresist polymer as claimed in claim 11, further comprising a second repeating unit represented by Chemical Formula 2: 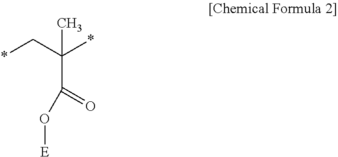
wherein, in Chemical Formula 2, E is a 1-valent acid-labile protecting group).

16. The photoresist polymer as claimed in claim 15, further comprising a third repeating unit represented by Chemical Formula 6: 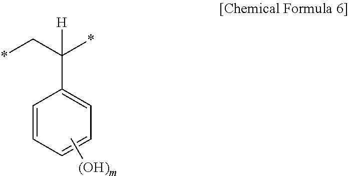
wherein, in Chemical Formula 6, m is an integer of 1 to 3.

17. The photoresist polymer as claimed in claim 16, wherein a molar proportion of the second repeating unit ranges from about 20 mol % to about 80 mol %, and a sum of a molar proportion of the first repeating unit and a molar proportion of the third repeating unit ranges from about 20 mol % to about 80 mol %, based on a total number of moles of repeating units of the photoresist polymer.

18. A photoresist composition, comprising:
a photoresist polymer including:
a first repeating unit represented by Chemical Formula 1 or 7, and
a second repeating unit represented by Chemical Formula 2;
a photoacid generator;
a photo-decomposable quencher; and
a solvent, 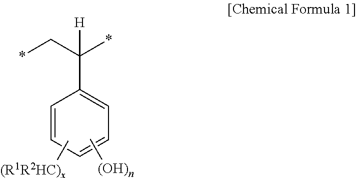
wherein, in Chemical Formula 1,
R¹ and R² are each independently a hydrogen atom, an alkyl group having 1 to 10 carbon atoms, an aryl group having 6 to 20 carbon atoms, or an aralkyl group having 7 to 20 carbon atoms, provided that at least one of R¹ and R² is not a hydrogen atom,
CHR¹R² is bonded at an ortho position or a para position with respect to a hydroxyl group of Chemical Formula 1, and
n and x are each an integer of 1 to 3, 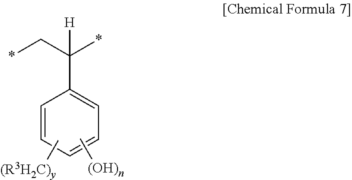
wherein, in Chemical Formula 7,
R³ is an aromatic ring having 6 to 20 carbon atoms,
CH₂R³ is bonded at an ortho position or a para position with respect to a hydroxyl group of Chemical Formula 7, and
n and y are each an integer of 1 to 3, 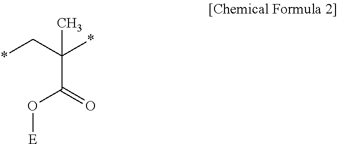
wherein, in Chemical Formula 2, E is a monovalent acid-labile protecting group.

19. The photoresist composition as claimed in claim 18, wherein:
the photoresist polymer further includes a third repeating unit represented by Chemical Formula 6: 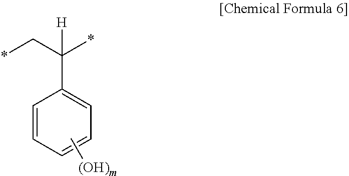
in Chemical Formula 6, m is an integer of 1 to 3.

20. The photoresist composition as claimed in claim 19, wherein a molar proportion of the second repeating unit ranges from about 20 mol % to about 80 mol %, and a sum of a molar proportion of the first repeating unit and a molar proportion of the third repeating unit ranges from about 20 mol % to about 80 mol %, based on a total number of moles of repeating units of the photoresist polymer.
